(19) United States
(12) Patent Application Publication
(10) Pub. No.: US 2018/0083018 A1
(43) Pub. Date: Mar. 22, 2018

(54) SEMICONDUCTOR MEMORY DEVICE AND METHOD OF MANUFACTURING THE SAME

(71) Applicant: Toshiba Memory Corporation, Tokyo (JP)

(72) Inventors: Shigehiro YAMAKITA, Yokkaichi Mie (JP); Yoshiaki FUKUZUMI, Yokkaichi Mie (JP); Wataru SAKAMOTO, Yokkaichi Mie (JP); Satoshi NAGASHIMA, Yokkaichi Mie (JP)

(21) Appl. No.: 15/688,826

(22) Filed: Aug. 28, 2017

Related U.S. Application Data
(60) Provisional application No. 62/396,374, filed on Sep. 19, 2016.

(51) Int. Cl. H01L 27/11517; H01L 27/1157; H01L 27/105; H01L 27/11524; H01L 29/788

(52) U.S. Cl. CPC H01L 27/11517; H01L 27/1157; H01L 29/788; H01L 27/11524; H01L 27/1052

(57) ABSTRACT

A semiconductor memory device includes a semiconductor substrate, a stepped structure including a stepped part in which a plurality of first insulating layers and conductive layers are alternately stacked on a main surface of the semiconductor substrate, the conductive layers including first, second, and third conductive layers, a second insulating layer which covers the stepped structure, a first contact interconnection which penetrates the second insulating layer and the first conductive layer in a thickness direction of the semiconductor substrate and is electrically connected to the second conductive layer, and a second contact interconnection which penetrates the second insulating layer and the second conductive layer in the thickness direction of the semiconductor substrate and is electrically connected to the third conductive layer.

### CROSS-REFERENCE TO RELATED APPLICATIONS

This application is based upon and claims the benefit of priority from U.S. Provisional Patent Application No. 62/396,374, filed on Sep. 19, 2016, the entire contents of which are incorporated herein by reference.

### FIELD

Embodiments described herein relate generally to a semiconductor memory device and a method of manufacturing the same.

### BACKGROUND

A NAND-type flash memory having a step-shaped end portion is known as one type of semiconductor memory device.

### BRIEF DESCRIPTION OF THE DRAWINGS

FIG. 1 is a block diagram illustrating a configuration example of a semiconductor memory device according to a first embodiment.

FIG. 2 is a perspective view of a memory cell array which constitutes a semiconductor memory device according to the first embodiment

FIG. 3 is a cross-sectional view taken along line 3-3 of the memory cell array shown in FIG. 2.

FIG. 4 is an enlarged cross-sectional view of a portion surrounded by region A in the memory cell array shown in FIG. 3.

FIGS. 5-12 are each a cross-sectional view of the memory cell array shown in FIG. 2 during different steps of manufacturing the semiconductor memory device according to the first embodiment.

FIG. 13 is a cross-sectional view of a memory cell array of a semiconductor memory device according to a modified example of the first embodiment.

FIG. 14 is an enlarged cross-sectional view of a portion surrounded by a region B in the memory cell array shown in FIG. 13.

FIG. 15 is an enlarged cross-sectional view of a portion surrounded by a region C in the memory cell array shown in FIG. 13.

FIG. 16 is a cross-sectional view of a memory cell array of a semiconductor memory device according to a second embodiment.

FIG. 17 is an enlarged cross-sectional view of a portion surrounded by a region D in the memory cell array shown in FIG. 16.

FIGS. 18-21 are each a cross-sectional view of the memory cell shown in FIG. 16 during different steps of manufacturing the semiconductor memory device according to the second embodiment.

FIG. 22 is a cross-sectional view of a memory cell array of a semiconductor memory device according to a modified example of the second embodiment.

FIG. 23 is an enlarged cross-sectional view of a portion surrounded by a region E in the memory cell array shown in FIG. 22.

FIG. 24 is an enlarged cross-sectional view of a portion surrounded by a region F in the memory cell array shown in FIG. 22.

### DETAILED DESCRIPTION

According to one embodiment, a semiconductor memory device includes a semiconductor substrate, a stepped structure including a stepped part in which a plurality of first insulating layers and conductive layers are alternately stacked on a main surface of the semiconductor substrate, the conductive layers including first, second, and third conductive layers, a second insulating layer which covers the stepped structure, a first contact interconnection which penetrates the second insulating layer and the first conductive layer in a thickness direction of the semiconductor substrate and is electrically connected to the second conductive layer, and a second contact interconnection which penetrates the second insulating layer and the second conductive layer in the thickness direction of the semiconductor substrate and is electrically connected to the third conductive layer.

Hereinafter, a semiconductor memory device and a method of manufacturing the same according to the embodiments will be described with reference to the drawings. In each of the drawings, the same components are denoted by the same reference numerals.

### First Embodiment

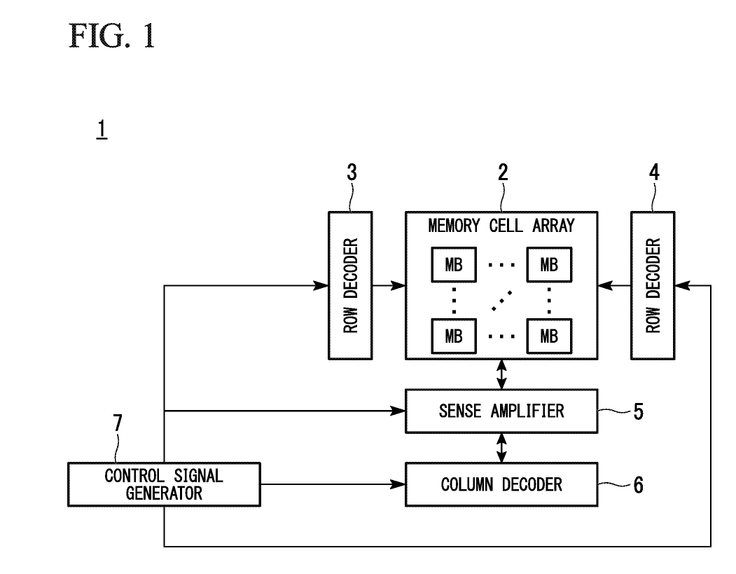

FIG. 1 is a block diagram illustrating a configuration example of a semiconductor memory device according to a first embodiment.

A semiconductor memory device 1 according to the first embodiment includes a memory cell array 2, row decoders 3 and 4, a sense amplifier 5, a column decoder 6, and a control signal generator 7.

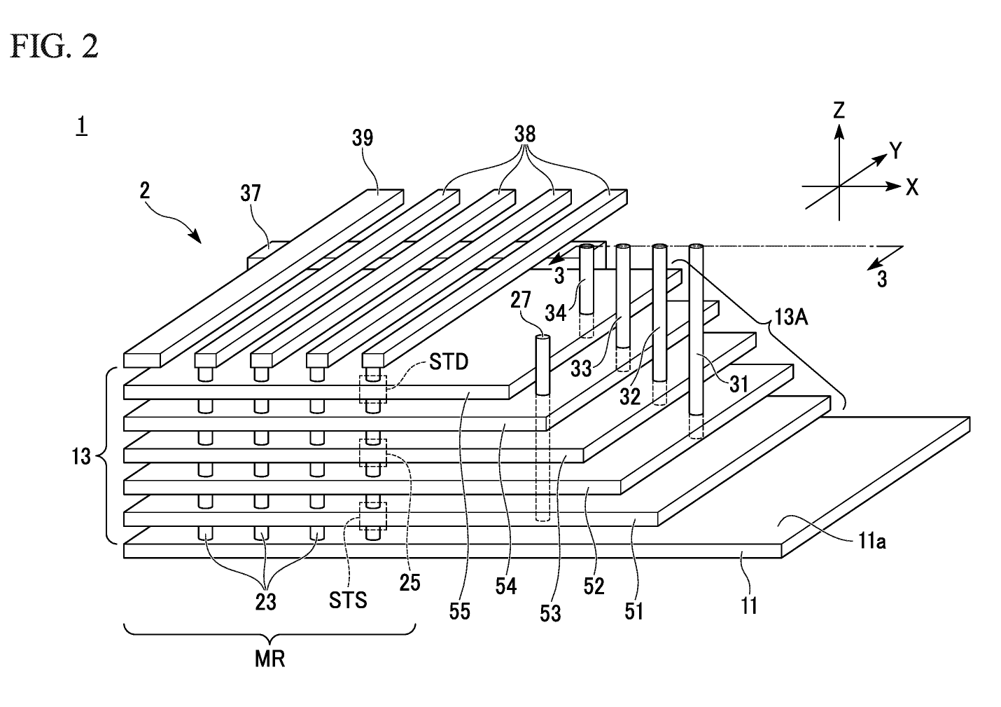

The memory cell array 2 includes a plurality of memory blocks MB. Each memory block MB includes a plurality of memory transistors MT (not shown in figure) which constitute a plurality of memory cells 25 arranged in three dimensions (shown later in FIG. 2). Each memory block MB is a unit for a data erasing operation. The memory blocks MB are separated from each other by a plurality of grooves extending in one direction.

The row decoders 3 and 4 decode a block address signal or the like transmitted from the control signal generator 7. The row decoders 3 and 4 control read and write operations of data in the memory cell array 2.

The sense amplifier 5 detects and amplifies an electrical signal flowing in the memory cell array 2 during the read operation.

The column decoder 6 decodes a column address signal sent from the control signal generator 7 and selectively extracts data by controlling the sense amplifier 5.

The control signal generator 7 generates control signals such as the block address signal and column address signal. The control signal generator 7 controls the row decoders 3 and 4, the sense amplifier 5, and the column decoder 6.

FIG. 2 is a perspective view of a memory cell array which constitutes a semiconductor memory device according to the first embodiment. In FIG. 2, the same components as in the semiconductor memory device 1 shown in FIG. 1 are designated by the same reference numerals. In FIG. 2, an X direction refers to an arrangement direction of conductive lines 38, a Y direction refers to an extending direction of the conductive lines 38 and a conductive line 39 perpendicular to the X direction, and a Z direction refers to a thickness direction of a semiconductor substrate 11. FIG. 2 shows an example of the memory cell array 2, and the number, disposition, and the like of each component are not limited to the position shown in FIG. 2.

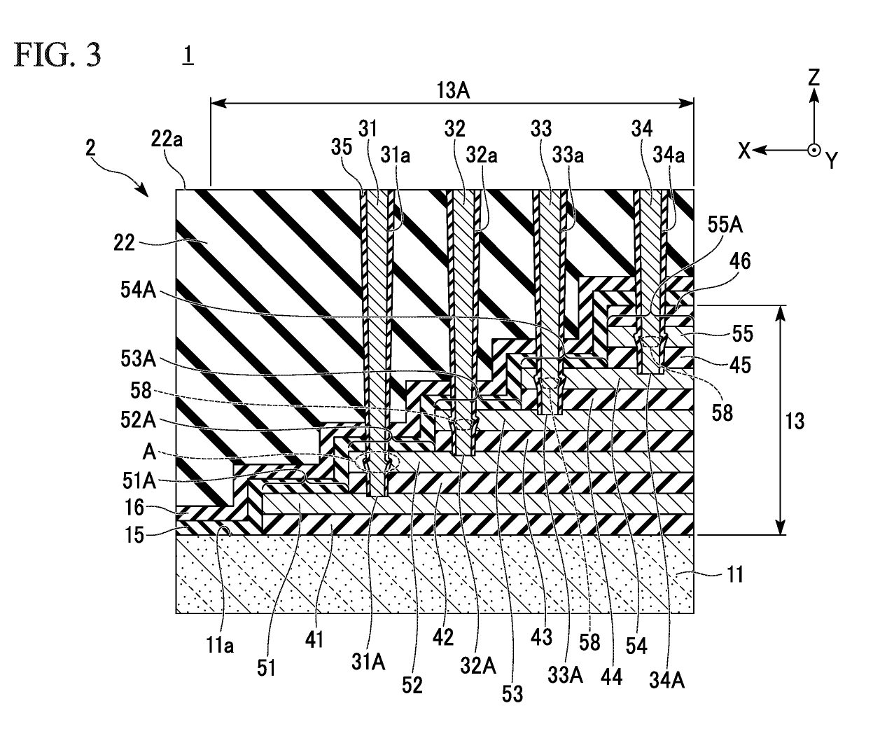

FIG. 3 is a cross-sectional view taken along line 3-3 of the memory cell array shown in FIG. 2. In FIG. 3, the same components as in the structures shown in FIGS. 1 and 2 are designated by the same reference numerals.

A first insulating film 35, a second insulating film 15, a third insulating film 16, first insulating layers 41 to 46, and a second insulating layer 22 which are shown in FIG. 3 are not shown in FIG. 2 to allow easier viewing of the drawing.

Referring to FIGS. 2 and 3, the memory cell array 2 of the semiconductor memory device 1 according to the first embodiment includes the semiconductor substrate 11, a stepped structure 13, the second insulating film 15, the third insulating film 16, the second insulating layer 22, memory columnar bodies 23, the memory cells 25, a beam columnar body 27, contact interconnections 31 to 34 (a plurality of contact interconnection), the first insulating film 35, a conductive portion 37, and the conductive lines 38 and 39.

The semiconductor substrate 11 has a main surface 11a. The semiconductor substrate 11 is, for example, a p-type single crystal silicon substrate.

The stepped structure 13 includes the first insulating layers 41 to 46 and conductive layers 51 to 55 which are alternately stacked on the main surface 11a of the semiconductor substrate 11.

The stepped structure 13 includes a stepped part 13A having a stepped structure at its end portion. The stepped structure refers to a structure in which, for example, when an end portion in the X direction of an (n)th layer component counted from the semiconductor substrate 11 side is at a negative side in the X direction with respect to an end portion in the X direction of an (n+1)th layer component, a correlation is maintained such that an end portion in the X direction of (n+2)th layer component is at a negative side in the X direction with respect to an end portion in the X-direction of the (n+1)th layer component.

The first insulating layer 41 is provided on the main surface 11a of the semiconductor substrate 11. The first insulating layers 41 to 46 are disposed to be stacked in a direction away from the semiconductor substrate 11.

Each thickness of the first insulating layers 41 to 46 may be made to be the same or different from each other. The first insulating layers 41 to 46 are, for example, silicon oxide films.

The conductive layers 51 to 55 are stacked such that end portions 52A to 55A of the upper conductive layers 52 to 55 are set back in the X direction relative to end portions 51A to 54A of the next lower conductive layers 51 to 54. The end portions MA to 55A of the conductive layers 51 to 55 are an end portion of the stepped structure 13. Each thickness of the conductive layers 51 to 55 may be made to be the same or different from each other.

Also, the end portions 51A to 55A of the conductive layers 51 to 55 refer to certain regions near the end surfaces of the conductive layers 51 to 55.

The conductive layer 51 disposed to be the lowermost conductive layer is a source-side selective gate electrode layer SGS of a source-side selective transistor STS. The conductive layer 55 disposed to be the uppermost conductive layer is a drain-side selective gate electrode layer SGD of a drain-side selective transistor STD.

The conductive layers 52 to 54 are gate electrode layers of the memory cells 25. The total number of the conductive layers can be arbitrarily defined.

The conductive layers 51 to 54 may include the same type of conductive material, for example. The same type of conductive material includes, for example, tungsten (W).

The second insulating film 15 is provided on the main surface 11a of the semiconductor substrate 11 and the stepped structure 13. The second insulating film 15 covers the stepped part 13A. The second insulating film 15 is, for example, a silicon oxide film.

The third insulating film 16 is provided on the second insulating film 15. The third insulating film 16 covers the second insulating film 15.

The third insulating film 16 is less likely to be etched as compared with the second insulating layer 22 and the second insulating film 15 with respect to the etching of the second insulating layer 22 and the second insulating film 15. The third insulating film 16 is, for example, a silicon nitride film.

The second insulating layer 22 is provided on the main surface 11a of the semiconductor substrate 11 and covers the stepped structure 13. An upper surface 22a of the second insulating layer 22 is a planarized surface. The second insulating layer 22 is, for example, a silicon oxide film.

A plurality of memory columnar bodies 23 are provided at a memory region MR (a region in which the stepped part 13A is not formed) in the main surface 11a of the semiconductor substrate 11. The memory columnar bodies 23 penetrate the stepped structure 13 in the Z direction. The memory columnar bodies 23 are disposed in an arbitrary layout on an X-Y plane.

An intersecting portion of the memory columnar body 23 and the conductive layer 51 is the source-side selective transistor STS. An intersecting portion of the memory columnar body 23 and the conductive layer 55 is the drain-side selective transistor STD.

Intersecting portions of the memory columnar bodies 23 and the conductive layers 52 to 54 are the memory cells 25.

The drain-side selective transistor STD, the plurality of memory cells 25, and the source-side selective transistor STS are connected in series.

The beam columnar body 27 penetrates the stepped structure 13 in the Z direction. The beam columnar body 27 reaches the main surface 11a of the semiconductor substrate 11.

The contact interconnections 31 to 34 penetrate the second insulating film 15 and the third insulating film 16 which are provided at the stepped part 13A, and the second insulating layer 22 in the Z direction.

Each of the contact interconnections 31 to 34 is electrically connected to one conductive layer among the conductive layers 51 to 54. Lower end portions of the contact interconnections 31 to 34 are individually joined to the conductive layer to which each of the contact interconnections 31 to 34 is electrically connected.

The term “join” means not only a state in which lower end surfaces of the contact interconnections 31 to 34 are in contact with the conductive layers 51 to 54 but also a state in which the lower end portions of the contact interconnections 31 to 34 are implanted in the conductive layers 51 to 54 and in which the lower end surfaces and a portion of the side surfaces of the contact interconnections 31 to 34 are in contact with the conductive layers 51 to 54.

For example, a lower end 31A of the contact interconnection 31 is closest to the main surface 11a of the semiconductor substrate 11 among the lower ends of the contact interconnections 31 to 34. A lower end 34A of the contact interconnection 34 is farthest from the main surface 11a of the semiconductor substrate 11 among the lower ends of the contact interconnections 31 to 34. A lower end 32A of the contact interconnection 32 is closer to the main surface 11a of the semiconductor substrate 11 than a lower end 33A of the contact interconnection 33.

Hereinafter, connection structures of the contact interconnections 31 to 34 and the conductive layers 51 to 55 will be described in detail.

The lower end 31A of the contact interconnection 31 is disposed in the conductive layer 51. The contact interconnection 31 penetrates the end portion 52A of the conductive layer 52 and the first insulating layer 42 which are provided on the side opposite to the main surface 11a of the semiconductor substrate 11 with respect to the conductive layer 51.

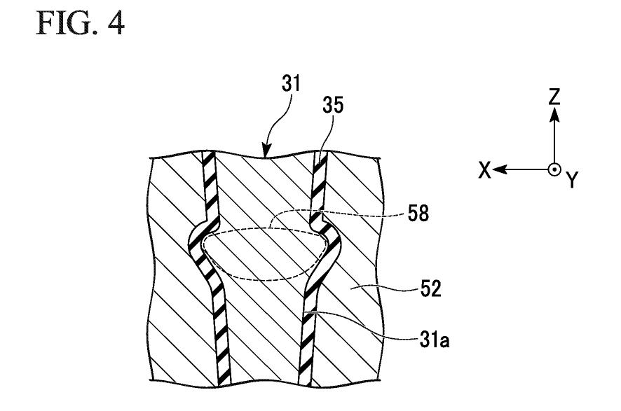

FIG. 4 is an enlarged cross-sectional view of a portion surrounded by a region A in the memory cell array shown in FIG. 3.

The contact interconnection 31 has an enlarged diameter portion 58 at a portion penetrating the conductive layer 52. The enlarged diameter portion 58 is enlarged in diameter compared to upper and lower portions thereof.

The enlarged diameter portion 58 is a portion in which a diameter of an interconnection line is enlarged in the middle of a length direction of the interconnection line in the substantially tubular contact interconnection 31.

The lower end 32A of the contact interconnection 32 is disposed in the conductive layer 52. The contact interconnection 32 penetrates an end portion 53A of the conductive layer 53, and the first insulating layer 43. The contact interconnection 32 has the enlarged diameter portion 58 at a portion penetrating the conductive layer 53.

The lower end 33A of the contact interconnection 33 is disposed in the conductive layer 53. The contact interconnection 33 penetrates an end portion 54A of the conductive layer 54, and the first insulating layer 44. The contact interconnection 33 has the enlarged diameter portion 58 at a portion penetrating the conductive layer 54.

The lower end 34A of the contact interconnection 34 is disposed in the conductive layer 54. The contact interconnection 34 penetrates an end portion 55A of the conductive layer 55, and the first insulating layers 45 and 46. The contact interconnection 34 has the enlarged diameter portion 58 at a portion penetrating the conductive layer 55.

The contact interconnections 31 to 34 penetrate conductive layers of the same number, individually.

As shown in FIG. 3, the first insulating film 35 covers each of side surfaces 31a to 34a of the contact interconnections 31 to 34. Portions through which the contact interconnections 31 to 34 penetrate in the conductive layers 52 to 55 are covered by the first insulating film 35.

The conductive portion 37 is provided on the main surface 11a of the semiconductor substrate 11. The conductive portion 37 extends in the X-Z plane direction. In the Y direction, the conductive portion 37 faces side end surfaces of the conductive layers 51 to 55.

The plurality of conductive lines 38 extend in the Y direction and are arranged in the X direction. The plurality of conductive lines 38 are bit lines (BL).

The conductive line 39 is provided on an upper end of the conductive portion 37. The conductive line 39 extends in the Y direction. The conductive line 39 is a source line (SL).

The conductive portion 37, the plurality of conductive lines 38 and the conductive line 39 may include, for example, tungsten (W).

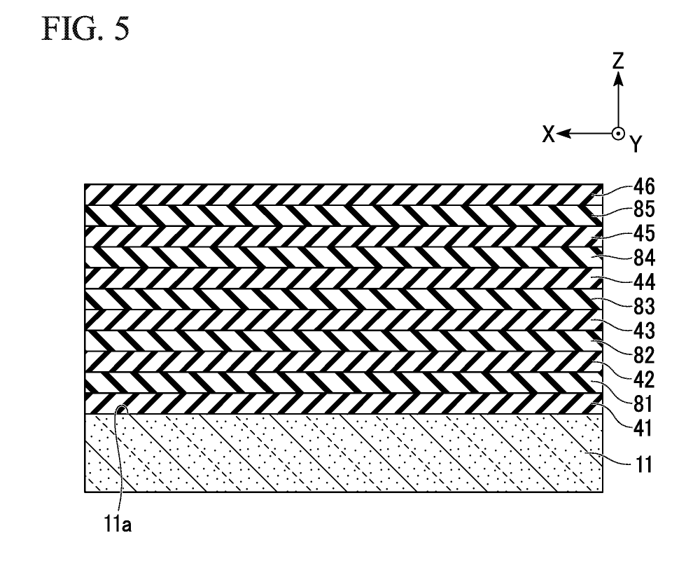

A method of manufacturing the semiconductor memory device 1 of the first embodiment will be described with reference to FIGS. 5 to 12.

FIGS. 5 to 12 are cross-sectional views of the memory cell array shown in FIG. 2 during different steps of manufacturing the semiconductor memory device according to the first embodiment, and correspond to cross-sections in which the contact interconnections 31 to 34 are sectioned on a plane perpendicular to both of the main surface 11a of the semiconductor substrate 11 of the semiconductor memory device 1 and the Y direction.

To obtain the structure shown in FIG. 5, the first insulating layers 41 to 46 and first sacrificial insulating layers 81 to 85 are alternately stacked on the main surface 11a of the semiconductor substrate 11 in the Z direction.

The first sacrificial insulating layers 81 to 85 are a different type of film from the first insulating layers 41 to 46 and are films capable of having an etch selectivity with respect to the first insulating layers 41 to 46.

As the first insulating layers 41 to 46, for example, silicon oxide film may be used. As the first sacrificial insulating layers 81 to 85, for example, a silicon nitride film may be used.

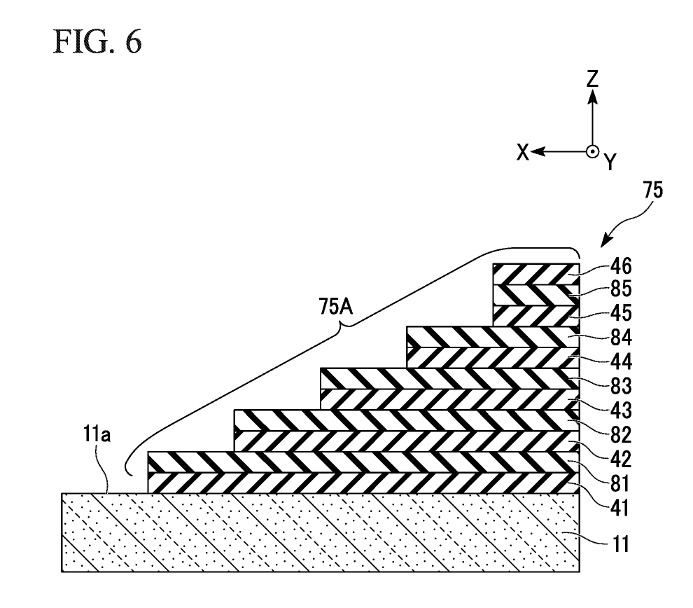

To obtain the structure shown in FIG. 6, the first insulating layers 41 to 46 and the first sacrificial insulating layers 81 to 85 are formed such that upper layers of the first insulating layers 42 to 46 and the first sacrificial insulating layers 81 to 85 are further set back than next lower layers of the first insulating layers 41 to 44 and the first sacrificial insulating layers 81 to 84 to form a step layered body 75 including a stepped part 75A at an end portion thereof.

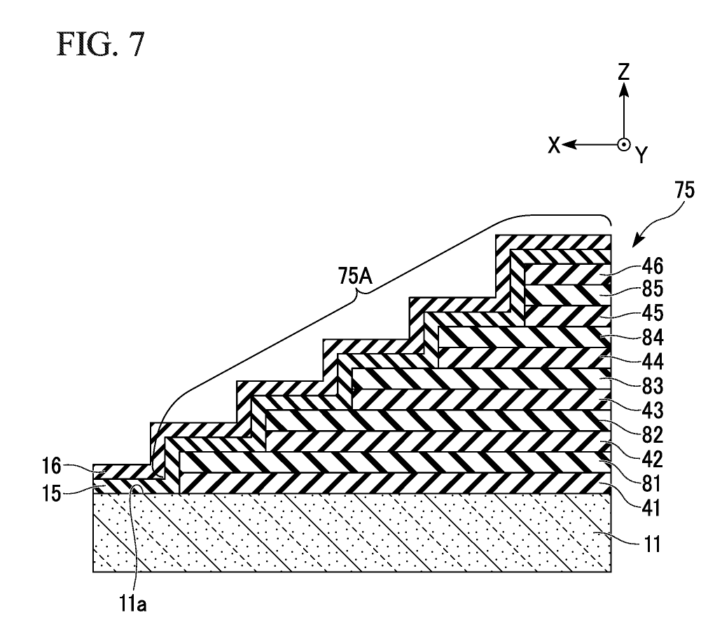

To obtain the structure shown in FIG. 7, the second insulating film 15 which covers an upper surface of the step layered body 75 is formed and then the third insulating film 16 which covers an upper surface of the second insulating film 15 is formed. The third insulating film 16 is formed by depositing a film which is less likely to be etched as compared with the second insulating layer 22 and the second insulating film 15 with respect to the etching of the second insulating layer 22 and the second insulating film 15.

As the second insulating film 15, for example, a silicon oxide film may be used. As the third insulating film 16, for example, a silicon nitride film may be used.

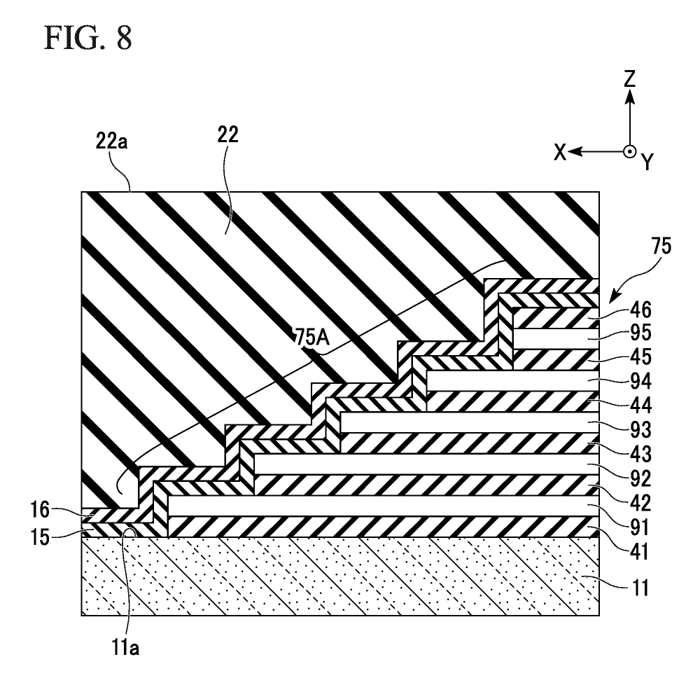

To obtain the structure shown in FIG. 8, the second insulating layer 22 which covers an upper surface of the third insulating film 16 is formed, and then an upper surface of the deposited second insulating layer 22 is ground to form the planarized upper surface 22a. The second insulating layer 22 may be formed, for example, by depositing a silicon oxide.

The beam columnar body 27, which is shown in FIG. 2, is then formed by penetrating the second insulating layer 22 and the step layered body 75 in the Z direction.

As shown in FIG. 8, a plurality of spaces 91 to 95 are formed by selectively removing the first sacrificial insulating layers 81 to 85 by wet-etching process. As the etchant, for example, thermal phosphoric acid may be used.

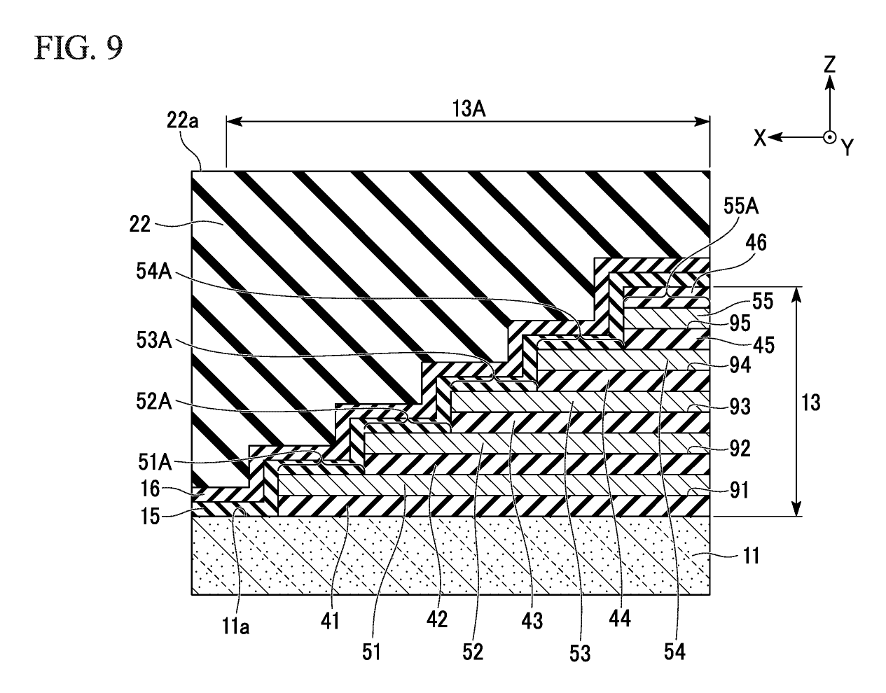

To obtain the structure shown in FIG. 9, the plurality of conductive layers 51 to 55 are collectively formed by depositing a conductive film in the plurality of the spaces 91 to 95. The conductive film may be, for example, a tungsten film.

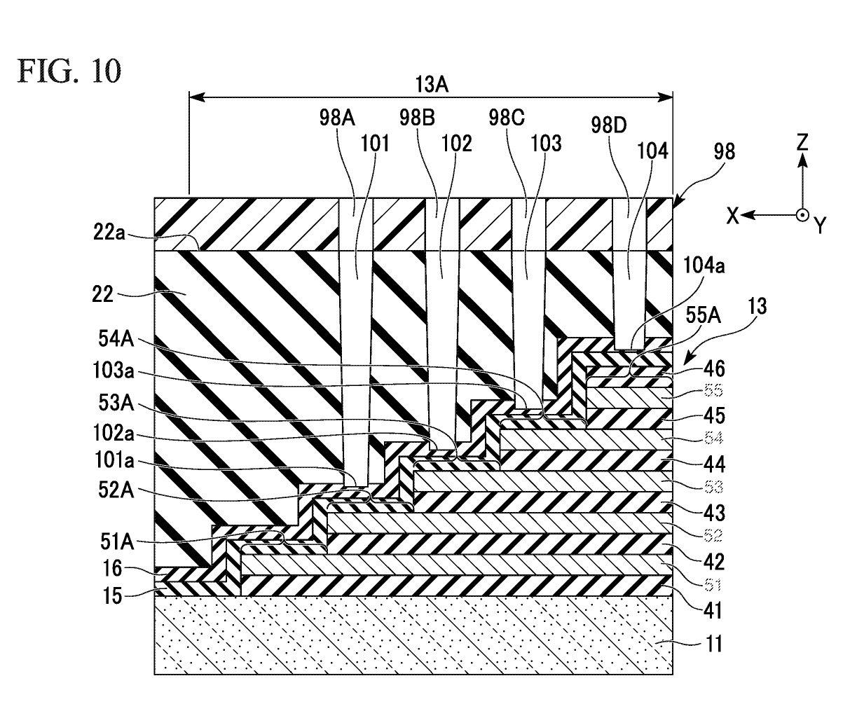

To obtain the structure shown in FIG. 10, an etching mask 98 including openings 98A to 98D is formed on the upper surface 22a of the second insulating layer 22.

The opening 98A is formed above the end portion 52A. The opening 98B is formed above the end portion 53A. The opening 98C is formed above the end portion 54A. The opening 98D is formed above the end portion 55A.

First contact hole portions 101 to 104 having a depth at which bottoms 101a to 104a thereof reach the third insulating film 16 are formed by selectively performing anisotropic etching on the second insulating layer 22 formed under the openings 98A to 98D.

As the etching gas for the anisotropic etching, for example, a mixed gas in which C₄H₈ gas, C₄F₆ gas, Ar gas, and O₂ gas are mixed may be used. The third insulating film 16 serves as an etching stopper when the above-described etching gas is used.

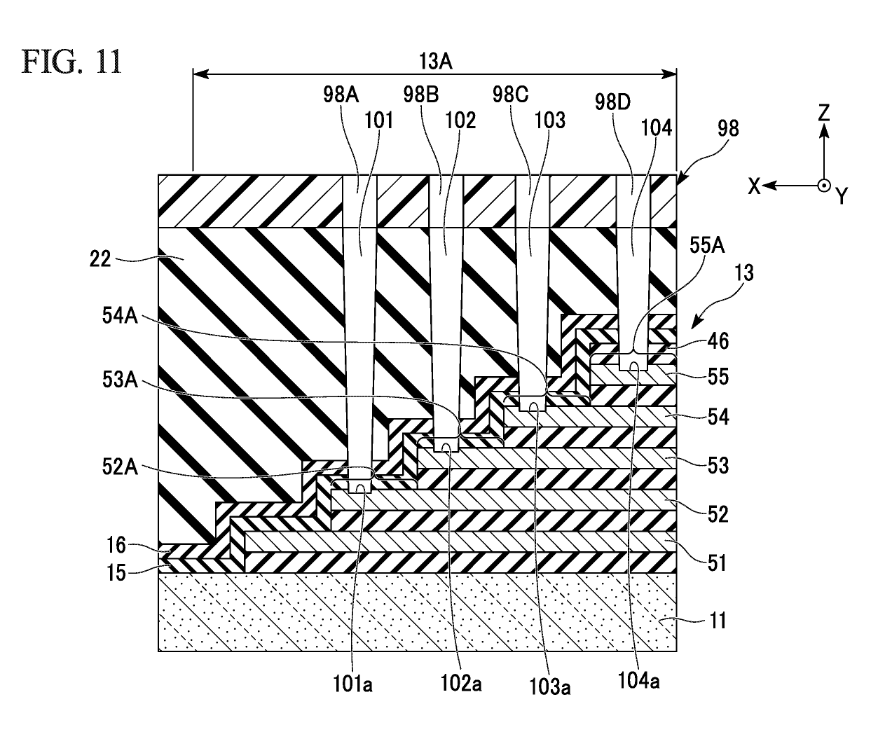

To obtain the structure shown in FIG. 11, the third insulating film 16 is selectively etched, and the second insulating film 15 is exposed by etching the third insulating film 16 positioned under the first contact hole portions 101 to 104 by anisotropic dry etching using the condition that is non-selective with respect to the second insulating film 15.

As the etching gas for the anisotropic etching, for example, a mixed gas in which CHF₃ gas and CO gas are mixed may be used. The second insulating film 15 serves as an etching stopper when the above-described etching gas is used.

As shown in FIG. 11, the second insulating film 15 and the first insulating layer 46 are selectively etched, and as a result the bottoms 101a to 104a of the first contact hole portions 101 to 104 respectively reach the conductive layers 52 to 55 formed above the predetermined conductive layers 51 to 54 when the second insulating film 15 and the first insulating layer 46 are selectively etched by the anisotropic dry etching using the condition that is non-selective with respect to the conductive layers 52 to 55.

As the etching gas for the anisotropic etching, for example, a mixed gas in which C₄F₆ gas, Ar gas, and O₂ gas are mixed may be used. The conductive layers 52 to 55 serve as an etching stopper when the above-described etching gas is used.

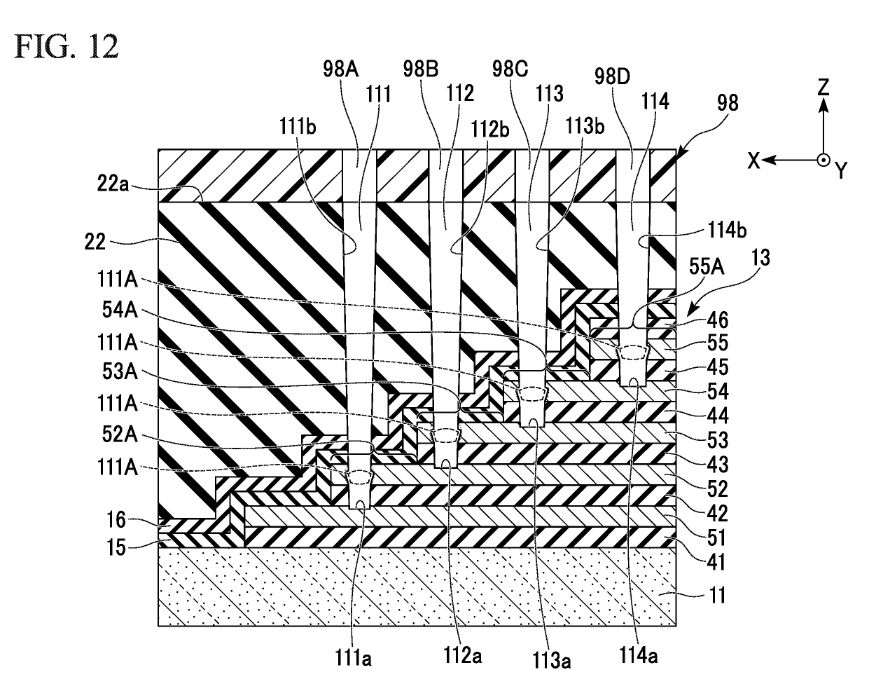

To obtain the structure shown in FIG. 12, the conductive layers 52 to 55 under the first contact hole portions 101 to 104 are selectively etched by the anisotropic dry etching using the condition that is non-selective with respect to the first insulating layers 42 to 45.

As the etching gas for the anisotropic etching, for example, a mixed gas in which C₄H₈ gas, Ar gas, and O₂ gas are mixed may be used.

Subsequently, the first insulating layers 42 to 45 are selectively etched, and bottoms 111a to 114a reach the predetermined conductive layers 51 to 54 when the first insulating layers 42 to 45 are removed by the anisotropic dry etching using the condition that is non-selective with respect to the conductive layers 51 to 54 in order to form contact holes 111 to 114 having depths different from each other.

At this time, an upper portion of the conductive layers 52 to 55 in a layer thickness direction is eroded in an X-Y plane direction due to the etching gas and a space is formed. An inner diameter of the contact holes 111 to 114 in the conductive layers 52 to 55 is enlarged due to the space formed in the conductive layers 52 to 55. As a result of the inner diameter being enlarged at a portion of the contact holes, an enlarged diameter region 111A is formed in the contact holes. The enlarged diameter region 111A is a region whose diameter is enlarged compared to the other regions formed in upper and lower directions of the contact hole portions 101 to 104.

The contact holes 111 to 114 individually penetrate one of the conductive layers 52 to 55 disposed above the predetermined conductive layers 51 to 54. The contact holes 111 to 114 individually penetrate the conductive layers of the same number.

The bottoms 111a and 114a of the contact holes 111 to 114 do not penetrate the predetermined conductive layers 51 to 54.

As shown in FIG. 3, the etching mask 98 is removed to form the first insulating film 35 which covers only side walls 111b to 114b of the plurality of contact holes 111 to 114. The first insulating film 35 is, for example, a silicon oxide film.

The first insulating film 35 is also formed at the enlarged diameter region 111A. An inner surface of the first insulating film 35 at the enlarged diameter region 111A is shaped to be recessed in the X-Y plane direction at the enlarged diameter region 111A reflecting a shape of the enlarged diameter region 111A.

A conductive film is deposited in the entire internal space of the contact holes 111 to 114 in which the first insulating film 35 is formed to collectively form the contact interconnections 31 to 34 having the enlarged diameter portion 58 formed at the enlarged diameter region 111A. The conductive film is, for example, a tungsten film.

As a result, the contact interconnections 31 to 34 are respectively connected to the conductive layers 51 to 54.

In the first embodiment, since the contact interconnections 31 to 34 are provided to penetrate the conductive layers 52 to 55 above the predetermined conductive layers 51 to 54, it can be used as a stopper when the contact holes 111 to 114 in which the contact interconnections 31 to 34 are provided are formed.

Therefore, since the contact interconnections 31 to 34 can reach the predetermined conductive layers 51 to 54 without penetrating the predetermined conductive layers 51 to 54, a process margin can be extended.

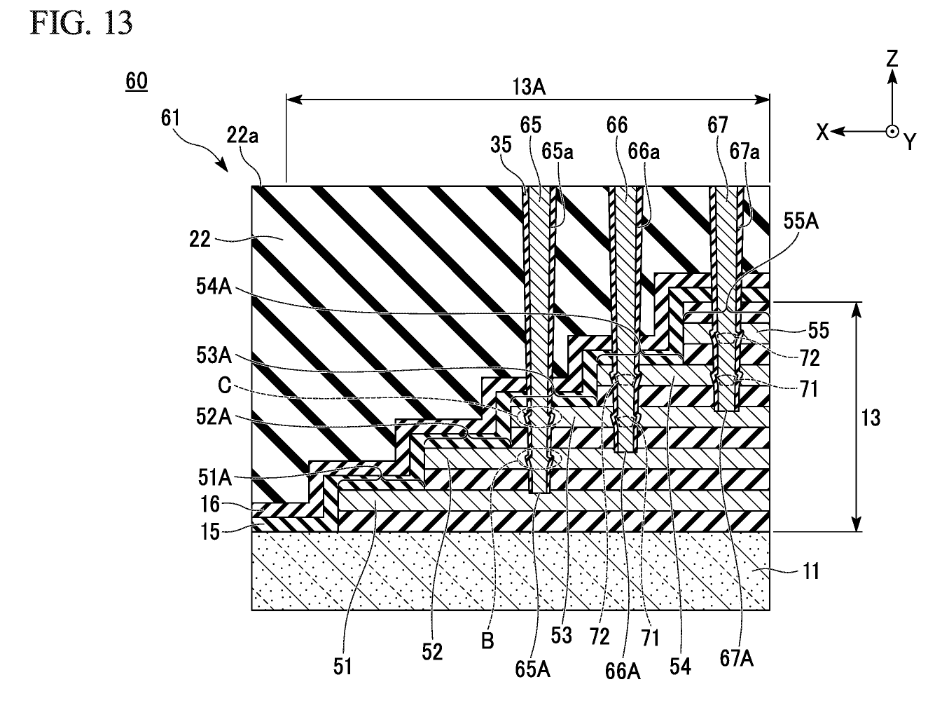

FIG. 13 is a cross-sectional view of a memory cell array of a semiconductor memory device according to a modified example of the first embodiment. In FIG. 13, the same components as in the memory cell array 2 of the semiconductor memory device 1 of the first embodiment shown in FIG. 3 are designated by the same reference numerals.

Referring to FIG. 13, a memory cell array 61 of a semiconductor memory device 60 according to the modified example of the first embodiment is different from the memory cell array 2 of the first embodiment in that contact interconnections 65 to 67 are provided instead of the contact interconnections 31 to 34.

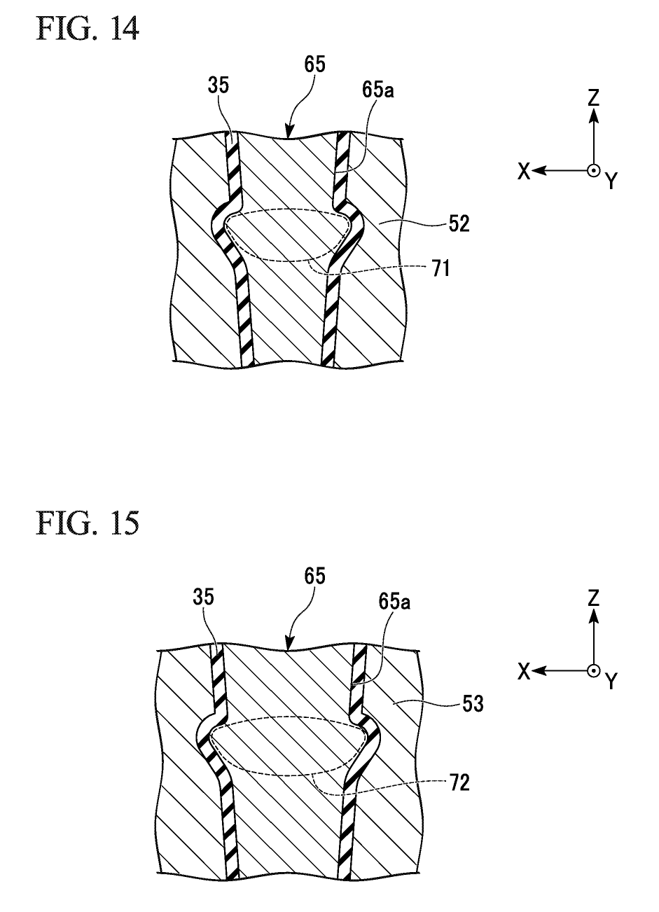

FIG. 14 is an enlarged cross-sectional view of a portion surrounded by a region B in the memory cell array shown in FIG. 13. FIG. 15 is an enlarged cross-sectional view of a portion surrounded by a region C in the memory cell array shown in FIG. 13.

The contact interconnection 65 penetrates the end portion 53A of the conductive layer 53, and the conductive layer 52 in the Z direction, and the bottom 65A thereof reaches the conductive layer 51. The contact interconnection 65 has an enlarged diameter portion 71 disposed in the conductive layer 52 and an enlarged diameter portion 72 disposed in the end portion 53A of the conductive layer 53.

The enlarged diameter portion 71 is disposed below the enlarged diameter portion 72. A diameter of the enlarged diameter portion 71 disposed below the enlarged diameter portion 72 is smaller than a diameter of the enlarged diameter portion 72 due to a reason in manufacturing, that is, due to a micro loading effect generated in formation of the contact hole in which the contact interconnection 65 is formed.

The contact interconnection 66 is configured similar to the contact interconnection 65 except that the contact interconnection 66 penetrates the conductive layer 53 and the end portion 54A of the conductive layer 54 in the Z direction and the bottom 66A reaches the conductive layer 52.

The contact interconnection 67 is configured similar to the contact interconnection 66 except that the contact interconnection 67 penetrates the conductive layer 54 and the end portion 55A of the conductive layer 55 in the Z direction and the bottom 67A reaches the conductive layer 53. The first insulating film 35 is provided on side surfaces 65a to 67a of the contact interconnections 65 to 67.

Therefore, the contact interconnections 65 to 67 may penetrate two conductive layers.

Also, the contact interconnections 65 to 67 may penetrate three or more of the conductive layers 52 to 55. Preferably, the contact interconnections 65 to 67 penetrate the same number of conductive layers.

### Second Embodiment

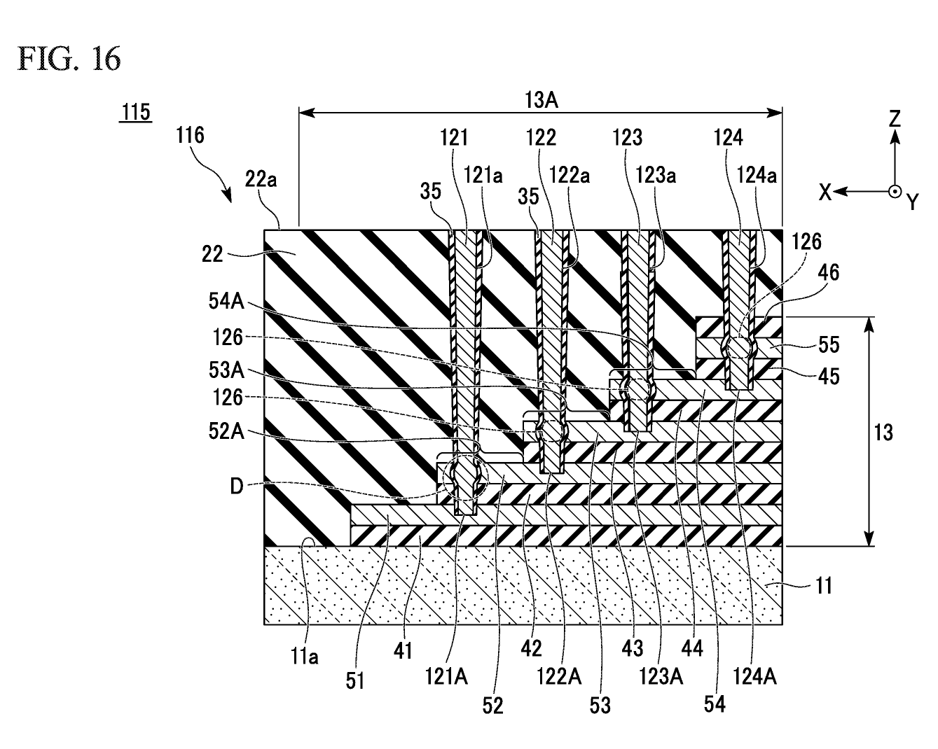

FIG. 16 is a cross-sectional view of a memory cell array of a semiconductor memory device according to a second embodiment. In FIG. 16, the same components as in the memory cell array 2 of the semiconductor memory device 1 of the first embodiment shown in FIG. 3 are designated by the same reference numerals.

A memory cell array 116 of a semiconductor memory device 115 of the second embodiment is configured similar to the memory cell array 2 except that the first and the second insulating films 15 and 16 are excluded from the constituent elements and contact interconnections 121 to 124 are provided instead of the contact interconnections 31 to 34.

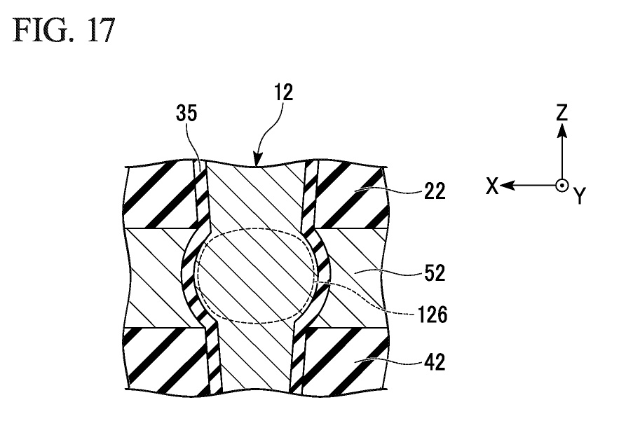

FIG. 17 is an enlarged cross-sectional view of a portion surrounded by a region D in the memory cell array shown in FIG. 16.

Referring to FIGS. 16 and 17, the contact interconnections 121 to 124 are configured similar to the contact interconnections 31 to 34 except that an enlarged diameter portion 126 is provided instead of the enlarged diameter portion 58.

The enlarged diameter portion 126 is different from the enlarged diameter portion 58 in that the enlarged diameter portion 126 is formed throughout the entire thickness of the conductive layers 52 to 55 in the Z direction.

The first insulating film 35 is provided on side surfaces 121a to 124a of the contact interconnections 121 to 124.

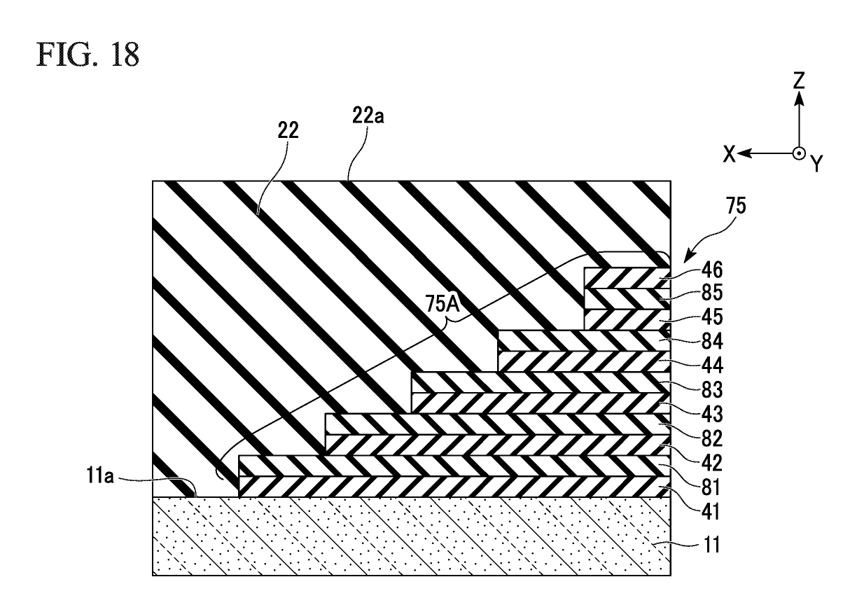

A method of manufacturing the semiconductor memory device 115 of the second embodiment will be described with reference to FIGS. 18 to 21.

FIGS. 18 to 21 are cross-sectional views of the memory cell shown in FIG. 16 during different steps of manufacturing the semiconductor memory device according to the second embodiment. In FIGS. 18 to 21, the same components as in the structures shown in FIGS. 16 and 17 are designated by the same reference numerals.

To obtain the structure shown in FIG. 18, the same processing as the processing described with reference to FIGS. 5 and 6 is performed to form a step layered body 75 including a stepped part 75A at an end portion thereof, and then a second insulating layer 22 which covers the step layered body 75 is formed, and then an upper surface of the deposited second insulating layer 22 is ground to form the planarized upper surface 22a.

A stepped structure 13 including a stepped part 13A is formed by forming conductive layers 51 to 55 by performing the same processing as the processing described with reference to FIGS. 8 and 9.

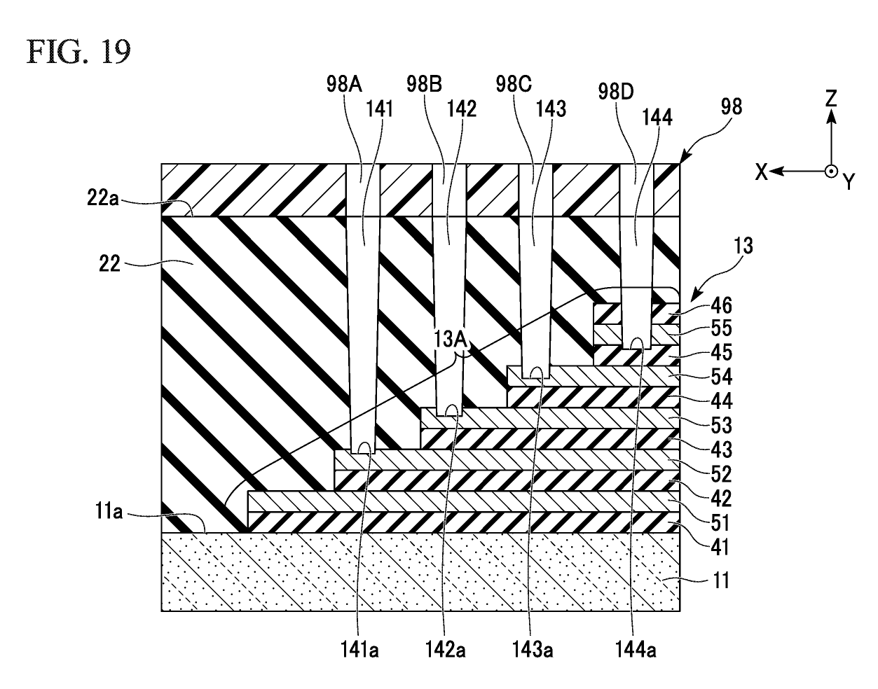

To obtain the structure shown in FIG. 19, an etching mask 98 including openings 98A to 98D is formed on the upper surface 22a of the second insulating layer 22.

Next, the second insulating layer 22 and a first insulating layer 46 are selectively etched, and first contact hole portions 141 to 144 having depths reaching the conductive layers 52 to 55 formed above the predetermined conductive layers 51 to 54 are formed by etching the second insulating layer 22 and the first insulating layer 46 by the anisotropic dry etching using the condition that is non-selective with respect to the conductive layers 52 to 55.

As the etching gas for the anisotropic etching, for example, a mixed gas in which C₄F₆ gas, Ar gas, and O₂ gas are mixed may be used.

As shown in FIG. 19, there is a case in which the first contact hole portion 144 having the smallest depth penetrates the conductive layer 55 depending on the number of layers in the stepped structure 13, but the first insulating layer 45 is not penetrated.

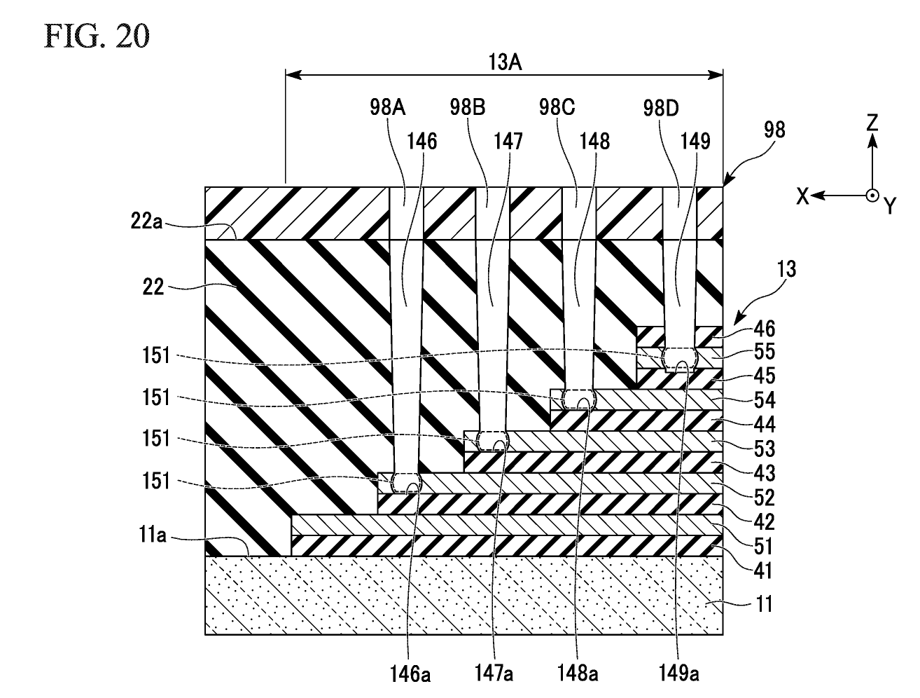

To obtain the structure shown in FIG. 20, the conductive layers 52 to 55 are further selectively etched, and second contact hole portions 146 to 149 which include the first contact hole portions 141 to 144 and penetrate the conductive layers 52 to 55 are formed by etching the conductive layers 52 to 55 to which the first contact hole portions 141 to 144 are exposed using an etchant that does not easily etch the first insulating layers 42 to 45.

By wet-etching process, an enlarged diameter portion 151 is formed in the second contact hole portions 146 to 149 at a portion corresponding to each of the conductive layers 52 to 55. Bottoms 146a to 149a of the second contact hole portions 146 to 149 reach the first insulating layers 42 to 45.

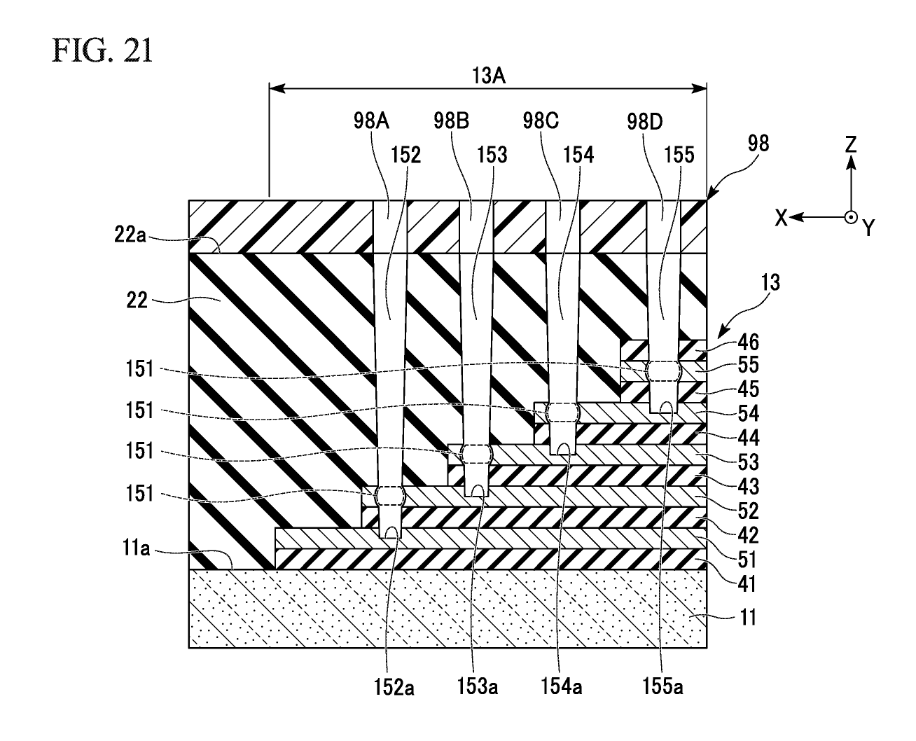

To obtain the structure shown in FIG. 21, contact holes 152 to 155, which include the second contact hole portions 146 to 149, whose bottoms 152a to 155a reach the predetermined conductive layers 51 to 54 are formed by etching the first insulating layers 42 to 45 positioned below the second contact hole portions by the anisotropic dry etching process.

Since the second insulating film 15 and the third insulating film 16 described in the first embodiment are not necessary in the second embodiment, the configuration and the manufacturing method can be simplified. The second embodiment can obtain an effect similar to the first embodiment.

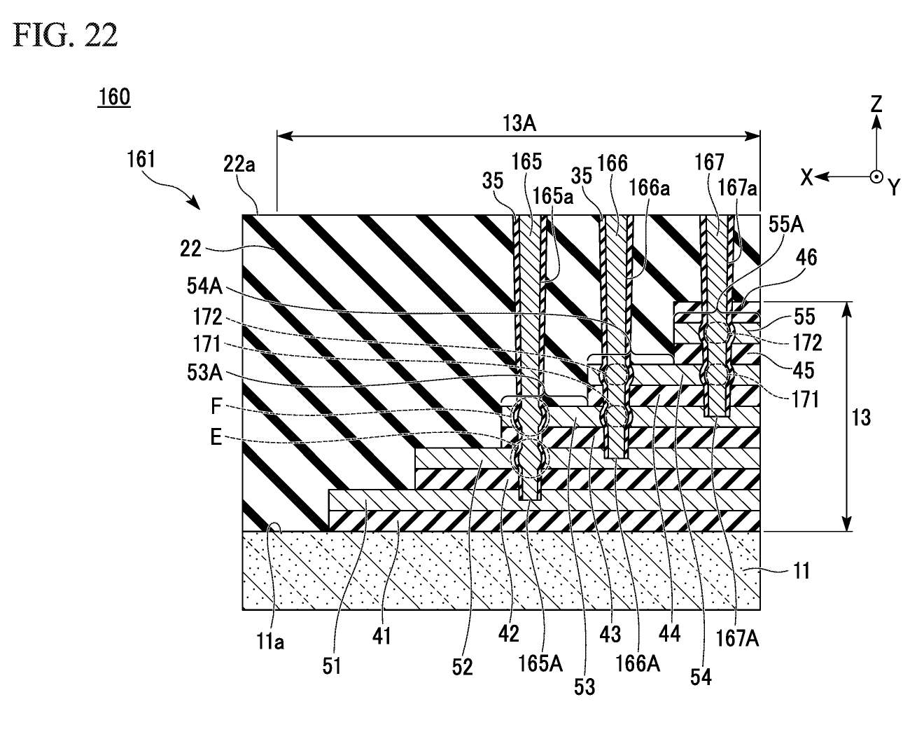

FIG. 22 is a cross-sectional view of a memory cell array of a semiconductor memory device according to a modified example of the second embodiment. In FIG. 22, the same components as in the memory cell array 116 of the semiconductor memory device 115 of the second embodiment shown in FIG. 16 are designated by the same reference numerals.

Referring to FIG. 22, a memory cell array 161 of a semiconductor memory device 160 according to the modified example of the second embodiment is different from the memory cell array 116 of the second embodiment in that the contact interconnections 165 to 167 are provided instead of the contact interconnections 121 to 124.

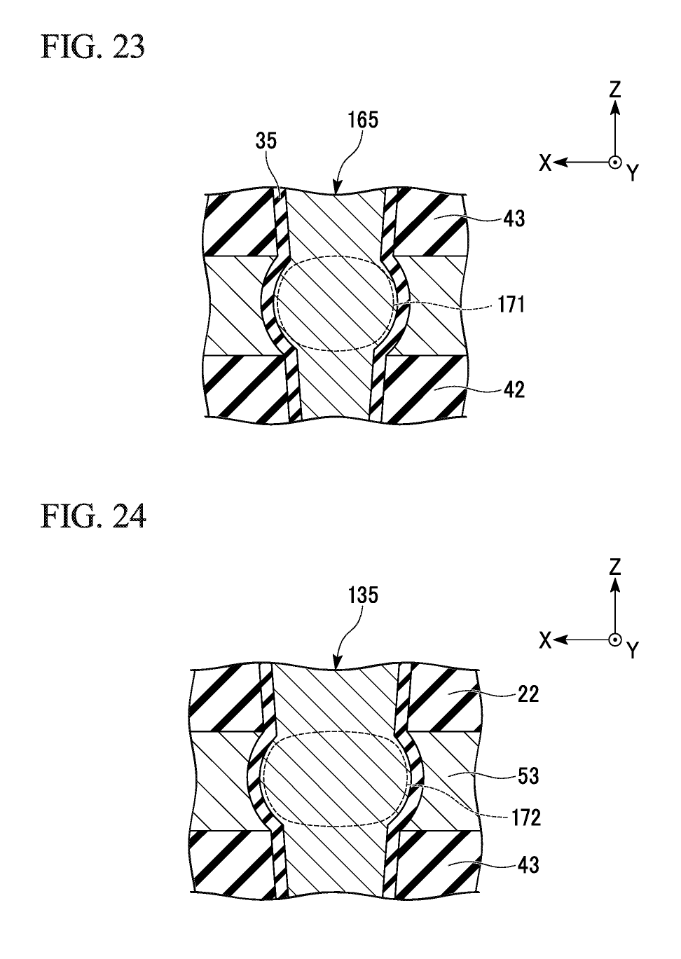

FIG. 23 is an enlarged cross-sectional view of a portion surrounded by a region E in the memory cell array shown in FIG. 22. FIG. 24 is an enlarged cross-sectional view of a portion surrounded by a region F in the memory cell array shown in FIG. 22.

Referring to FIGS. 22 and 23, the contact interconnection 165 penetrates the conductive layer 52 and the end portion 53A of the conductive layer 53 in the Z direction and the bottom 165A thereof reaches the conductive layer 51. The contact interconnection 165 has an enlarged diameter portion 171 disposed in the conductive layer 52 and an enlarged diameter portion 172 disposed in the end portion 53A of the conductive layer 53. The enlarged diameter portions 171 and 172 have similar shapes to the enlarged diameter portion 126 described above.

The contact interconnection 166 is configured similar to the contact interconnection 165 except that the contact interconnection 166 penetrates the conductive layer 53 and the end portion 54A of the conductive layer 54 in the Z direction and the bottom 166A reaches the conductive layer 52.

The contact interconnection 167 is configured similar to the contact interconnection 166 except that the contact interconnection 167 penetrates the conductive layer 54 and the end portion 55A of the conductive layer 55 in the Z direction and the bottom 167A reaches the conductive layer 53. The first insulating film 35 is provided on side surfaces 165a to 167a of the contact interconnections 165 to 167.

As described above, the contact interconnections 165 to 167 may penetrate two conductive layers. Also, the contact interconnections 165 to 167 may penetrate three or more of the conductive layers 52 to 55. Preferably, the contact interconnections 165 to 167 penetrate the same number of conductive layers.

In addition, although the case in which the stepped part 13A is one step stair is taken as an example in the first to third embodiment, the stepped part may be, for example, a grid-shaped step.

According to at least one embodiment described above, since the contact interconnections 31 to 34, 65 to 67, 121 to 124, and 165 to 167 individually penetrate at least one of conductive layers 52 to 55 above the predetermined conductive layers 51 to 54 to which the above-described contact interconnections are electrically connected, penetration through the predetermined conductive layers 51 to 54 by the contact interconnections 31 to 34, 65 to 67, 121 to 124, and 165 to 167 is suppressed, and thereby a process margin can be extended.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate;
a stepped structure including a stepped part in which a plurality of first insulating layers and conductive layers are alternately stacked on a main surface of the semiconductor substrate, the conductive layers including first, second, and third conductive layers;
a second insulating layer which covers the stepped structure;
a first contact interconnection which penetrates the second insulating layer and the first conductive layer in a thickness direction of the semiconductor substrate and is electrically connected to the second conductive layer; and
a second contact interconnection which penetrates the second insulating layer and the second conductive layer in the thickness direction of the semiconductor substrate and is electrically connected to the third conductive layer.

2. The semiconductor memory device according to claim 1, wherein the second conductive layer is between the first and third conductive layers in the thickness direction of the semiconductor substrate.

3. The semiconductor memory device according to claim 2, further comprising;
a third contact interconnection which penetrates the second insulating layer and the third conductive layer in the thickness direction of the semiconductor substrate and is electrically connected to another one of the conductive layer.

4. The semiconductor memory device according to claim 3, wherein the second contact interconnection is between the first and third contact interconnections.

5. The semiconductor memory device according to claim 1, wherein
the first contact interconnection also penetrates another one of the conductive layers above the first conductive layer in the thickness direction of the semiconductor substrate; and
the second contact interconnection also penetrates the first conductive layer in a thickness direction of the semiconductor substrate.

6. The semiconductor memory device according to claim 1, further comprising a first insulating film disposed on side surfaces of the first and second contact interconnections, wherein the first insulating film contacts portions of the plurality of conductive layers through which the first and second contact interconnections penetrate.

7. The semiconductor memory device according to claim 1, wherein the first and second contact interconnections each penetrate the same number of conductive layers.

8. The semiconductor memory device according to claim 1, wherein each of the first and second contact interconnections includes an enlarged diameter portion having an enlarged diameter compared to upper and lower portions thereof that are surrounded by the same conductive layer.

9. The semiconductor memory device according to claim 1, further comprising:
a third insulating layer which covers the second insulating layer, wherein
the second insulating layer is a silicon oxide layer, and the third insulating layer is a silicon nitride layer.

10. A method of manufacturing a semiconductor memory device comprising:
forming a stepped structure including a stepped part in which a plurality of first insulating layers and conductive layers are alternately stacked on a main surface of a semiconductor substrate, the conductive layers including first, second, and third conductive layers;
forming a second insulating layer which covers the stepped structure;
forming a first contact hole which penetrates the second insulating layer and the first conductive layer in a thickness direction of the semiconductor substrate and reaches the second conductive layer, and a second contact hole which penetrates the second insulating layer and the second conductive layer in the thickness direction of the semiconductor substrate and reaches the third conductive layer; and
depositing conductive material in the first and second contact holes to form first and second contact interconnections, respectively.

11. The method of claim 10, wherein the forming of the contact hole comprises:
performing etching on the stepped structure to penetrate an upper conductive layer formed above a target conductive layer in the plurality of conductive layers until the target conductive layer is exposed.

12. The method of claim 11, wherein the first and second contact holes penetrate the same number of conductive layers.

13. The method of claim 11, further comprising:
forming a third insulating layer which covers the second insulating layer, wherein
the second insulating layer is a silicon oxide layer, and the third insulating layer is a silicon nitride layer.

14. The method of claim 13, wherein forming the stepped structure includes:
forming a stacked body including the plurality of first insulating layers and first sacrificial insulating layers which are alternately stacked on the main surface of the semiconductor substrate;
forming the second insulating layer which covers the stacked body;
etching the stacked body to remove the plurality of first sacrificial insulating layers; and
depositing conductive material in spaces created by removing the plurality of first sacrificial insulating layers.

15. The method of claim 14, wherein:
a silicon oxide film is used for the second insulating layer and the plurality of first insulating layers; and
a silicon nitride film is used for the plurality of first sacrificial insulating layers.

16. The method of claim 15, wherein the forming of the contact hole comprises:
forming a first contact hole portion having a depth reaching the first conductive layer by anisotropic dry etching;
forming a second contact hole portion by etching the first conductive layer that is exposed by the first contact hole portion; and
forming a third contact hole portion by etching the first insulating layer that is exposed by the second contact hole portion by anisotropic dry etching.

17. The method of claim 16, wherein forming the first contact hole portion includes:
etching the second insulating layer by the anisotropic dry etching with the third insulating film serving as an etch stopper.

18. The method of claim 10, further comprising:
forming a first insulating film which covers side walls of the first and second contact holes; and
depositing the conductive material in the first and second contact holes having the first insulating film formed on side walls thereof.

19. A method of manufacturing a semiconductor memory device, comprising:
forming a stepped structure including a stepped part in which a plurality of first insulating layers and conductive layers are alternately stacked on a main surface of a semiconductor substrate, the conductive layers including first, second, third, and fourth conductive layers;
forming a second insulating layer which covers the stepped structure; and
forming a first contact hole which penetrates the second insulating layer and the first and second conductive layers in a thickness direction of the semiconductor substrate, and reaches the third conductive layer, and a second contact hole which penetrates the second insulating layer and the second and third conductive layers in the thickness direction of the semiconductor substrate, and reaches the fourth conductive layer,
wherein the third conductive layer is the conductive layer to which a first contact interconnection formed in the first contact hole is electrically connected, and the fourth conductive layer is the conductive layer to which a second contact interconnection formed in the second contact hole is electrically connected.

20. The method of claim 19, wherein when forming of the contact hole, the first and second contact holes penetrate the same number of the conductive layers.
